(19) United States
(12) Patent Application Publication
(10) Pub. No.: US 2023/0207468 A1
(43) Pub. Date: Jun. 29, 2023

(54) STACKED STAIRCASE CMOS WITH BURIED POWER RAIL

(71) Applicant: INTERNATIONAL BUSINESS MACHINES CORPORATION, Armonk, NY (US)

(72) Inventors: Kangguo Cheng, Schenectady, NY (US); Juntao Li, Cohoes, NY (US); Shogo Mochizuki, Mechanicville, NY (US)

(21) Appl. No.: 17/563,653

(22) Filed: Dec. 28, 2021

(51) Int. Cl. H01L 23/535; H01L 21/74; H01L 21/8238; H01L 21/762; H01L 23/528; H01L 29/66

(52) U.S. Cl. CPC H01L 23/535; H01L 21/743; H01L 21/823814; H01L 21/823871; H01L 21/823821; H01L 21/76205; H01L 23/5286; H01L 29/66545

(57) ABSTRACT

Semiconductor devices and methods of forming the same include forming a buried power rail in a substrate, having a first dielectric liner of a first thickness separating the buried power rail from the substrate. An isolation structure is formed over the buried power rail, having a second dielectric liner of a second thickness, greater than the first thickness, separating the isolation structure from the substrate. A first transistor device is formed on the substrate. The first transistor device has a first width. A second transistor device is formed above the first transistor device, and has a second width smaller than the first width. A conductive contact is formed to the buried power rail.

### BACKGROUND

The present invention generally relates to semiconductor device fabrication, and, more particularly, to forming nanosheet complementary metal oxide semiconductor (CMOS) devices.

Stacking CMOS devices can increase transistor density, for example by stacking an n-type field effect transistor and a p-type field effect transistor vertically. Thus, rather the area consumed by the CMOS pair can be halved.

### SUMMARY

A method of forming a semiconductor device includes forming a buried power rail in a substrate, having a first dielectric liner of a first thickness separating the buried power rail from the substrate. An isolation structure is formed over the buried power rail, having a second dielectric liner of a second thickness, greater than the first thickness, separating the isolation structure from the substrate. A first transistor device is formed on the substrate. The first transistor device has a first width. A second transistor device is formed above the first transistor device, and has a second width smaller than the first width. A conductive contact is formed to the buried power rail.

A method of forming a semiconductor device includes forming a buried power rail in a substrate. The buried power rail has a first dielectric liner of a first thickness separating the buried power rail from the substrate. An isolation structure is formed over the buried power rail and has a second dielectric liner of a second thickness, greater than the first thickness, separating the isolation structure from the substrate. A first transistor device is formed on the substrate, the first transistor device having a first width. A second transistor device, above the first transistor device, having a second width smaller than the first width. A via is formed that exposes a portion of a source/drain structure of the first transistor device and that cuts partially through the second dielectric liner. A conductive material is deposited in the via to form a conductive contact to the buried power rail.

A semiconductor device includes a buried power rail in a substrate, having a first dielectric liner of a first thickness separating the buried power rail from the substrate. An isolation structure is over the buried power rail, having a second dielectric liner of a second thickness, greater than the first thickness, separating the isolation structure from the substrate. A first transistor device is on the substrate, and has a first width. A second transistor device is above the first transistor device and has a second width smaller than the first width. A conductive contact connects to the buried power rail.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a cross-sectional view of a step in the fabrication of stacked complementary metal oxide semiconductor (CMOS) devices, showing a stack of semiconductor layers that include channel layers and sacrificial layers, in accordance with an embodiment of the present invention;

FIG. 2 is a cross-sectional view of a step in the fabrication of stacked CMOS devices, showing the formation of a first hardmask pattern over the stack of semiconductor layers, in accordance with an embodiment of the present invention;

FIG. 3 is a cross-sectional view of a step in the fabrication of stacked CMOS devices, showing the deposition of a layer of second mask material over the first hardmask pattern, in accordance with an embodiment of the present invention;

FIG. 4 is a cross-sectional view of a step in the fabrication of stacked CMOS devices, showing an etch-back of the second mask material to form second masks, in accordance with an embodiment of the present invention;

FIG. 5 is a cross-sectional view of a step in the fabrication of stacked CMOS devices, showing an etch down into the stack of semiconductor layers and the formation of sacrificial spacers, in accordance with an embodiment of the present invention;

FIG. 6 is a cross-sectional view of a step in the fabrication of stacked CMOS devices, showing an etch down into the stack of semiconductor layers to etch trenches into the substrate, in accordance with an embodiment of the present invention;

FIG. 7 is a cross-sectional view of a step in the fabrication of stacked CMOS devices, showing the formation of a dielectric liner in the trenches, in accordance with an embodiment of the present invention;

FIG. 8 is a cross-sectional view of a step in the fabrication of stacked CMOS devices, showing the formation of a power rail in a trench, in accordance with an embodiment of the present invention;

FIG. 9 is a cross-sectional view of a step in the fabrication of stacked CMOS devices, showing formation of shallow trench isolation structures, in accordance with an embodiment of the present invention;

FIG. 10 is a cross-sectional view of a step in the fabrication of stacked CMOS devices, showing formation of top and bottom source/drain regions, in accordance with an embodiment of the present invention;

FIG. 11 is a cross-sectional view of a step in the fabrication of stacked CMOS devices, showing the formation of an interlayer dielectric and conductive contacts, in accordance with an embodiment of the present invention;

FIG. 12 is a top-down view of a stacked CMOS device, illustrating relationships between the devices and the conductive contacts, in accordance with an embodiment of the present invention;

FIG. 13 is a cross-sectional view of stacked CMOS devices, illustrating a gate stack structure, in accordance with an embodiment of the present invention; and

FIG. 14 is a block/flow diagram of a method of fabricating stacked CMOS devices, in accordance with an embodiment of the present invention.

### DETAILED DESCRIPTION

While stacking transistors, such as in complementary metal oxide semiconductor (CMOS) circuits, can improve areal device density, making electrical contact to the underlying device in the stack can be difficult. To reach the lower device, electrical contacts may extend laterally past the horizontal extent of the upper device, which increases the area occupied by the CMOS circuit. To address this challenge, stacked devices can be formed with a staircase structure. A buried power rail may be used to make contact with the lower device, thereby reducing the number of contacts that have to reach the lower device from above.

As will be described in greater detail below, the buried power rail may have a single-layer dielectric liner to maximize the rail's size and thereby to reduce the rail's resistance. A double-layer dielectric liner may be formed above the buried power rail to improve the robustness of the rail's contact and to prevent shorting between the buried power rail contacts and the substrate.

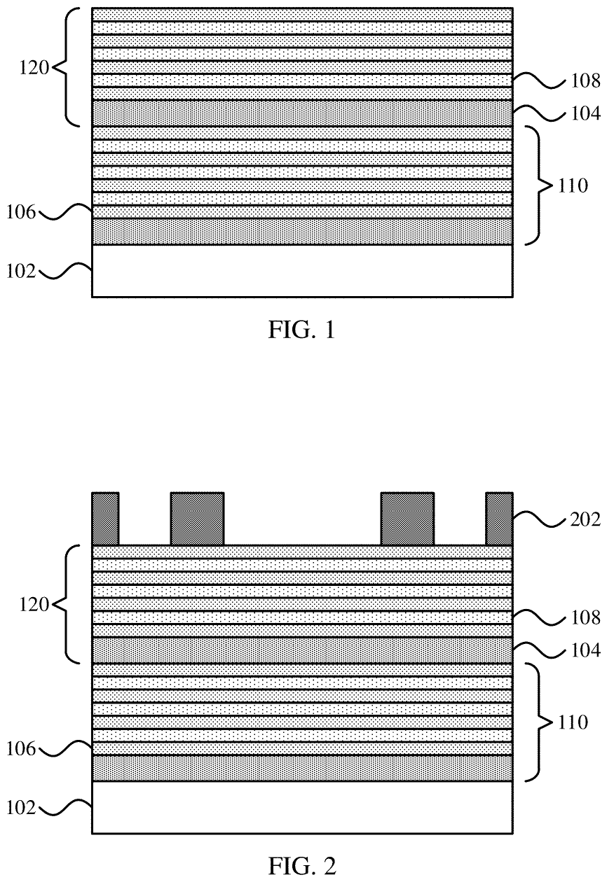

Referring now to FIG. 1, a cross-sectional view of a step in the fabrication of a stacked CMOS device is shown. A stack of layers is shown on a substrate 102, including a lower stack 110 and an upper stack 120. The lower stack 110 will be used to form a lower device, for example a p-type field effect transistor (pFET) or an n-type field effect transistor (nFET), and the upper stack 120 will be used to form an upper device, having a polarity that is complementary to the polarity of the lower device.

The semiconductor substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor on insulator (SOI) substrate.

The stacks of layers may be formed on the semiconductor substrate 102 by, e.g., successive epitaxial growth processes. The terms “epitaxial growth and/or deposition” refer to the growth of a semiconductor material on a deposition surface of a semiconductor material, in which the semiconductor material being grown has substantially the same crystalline characteristics as the semiconductor material of the deposition surface. The term “epitaxial material” denotes a material that is formed using epitaxial growth. In some embodiments, when the chemical reactants are controlled and the system parameters set correctly, the depositing atoms arrive at the deposition surface with sufficient energy to move around on the surface and orient themselves to the crystal arrangement of the atoms of the deposition surface. Thus, in some examples, an epitaxial film deposited on a {100} crystal surface will take on a {100} orientation.

The stacks of layers may therefore include channel semiconductor layers 108 made up of, e.g., silicon, first sacrificial semiconductor layers 106 made up of silicon germanium at a first germanium concentration, and second sacrificial semiconductor layers 104 made up of silicon germanium at a second germanium concentration. Varying the germanium concentration helps to improve selectivity in etching between the layers, so that layers with higher germanium concentrations may be preferentially etched relative to layers with lower germanium concentrations. For example, the first germanium concentration may be about 25% and the second germanium concentration may be about 50%. The second sacrificial semiconductor layers 104 may be used as placeholders for isolation structures that will electrically insulate the device of the lower stack 110 from the device of the upper stack 120 and from the substrate 102.

Although each stack is shown as having three channel semiconductor layers 108, it should be understood that any appropriate number of layers may be used. Additionally, although it is specifically contemplated that the layers may be nanosheet layers, it should be understood that nanowire layers may also be used. Taking a cross-section perpendicular to the illustrated view, a nanosheet may have a ratio of width to height that is greater than or equal about 2, while a nanowire may have a ratio of width to height that is smaller than about 2.

Besides nanosheet/nanowire transistors, other types of device are contemplated. For example, the transistors at top level and the bottom level can be fin field effect transistors (FinFETs) or planar transistors. Furthermore, the top transistor and the bottom transistor can have different transistors architectures. For example, the top transistor can be a FinFET and the bottom transistor can be a nanosheet transistor or vice versa.

Referring now to FIG. 2, a cross-sectional view of a step in the fabrication of a stacked CMOS device is shown. A first mask 202 is formed on top of the stack of layers. The first mask 202 may be formed by depositing a hardmask material, such as silicon nitride, and then patterning the hardmask material using a photolithographic process. The first mask 202 may be formed in two pairs of structures, with each pair having an internal separation that is smaller than a separation between the pairs.

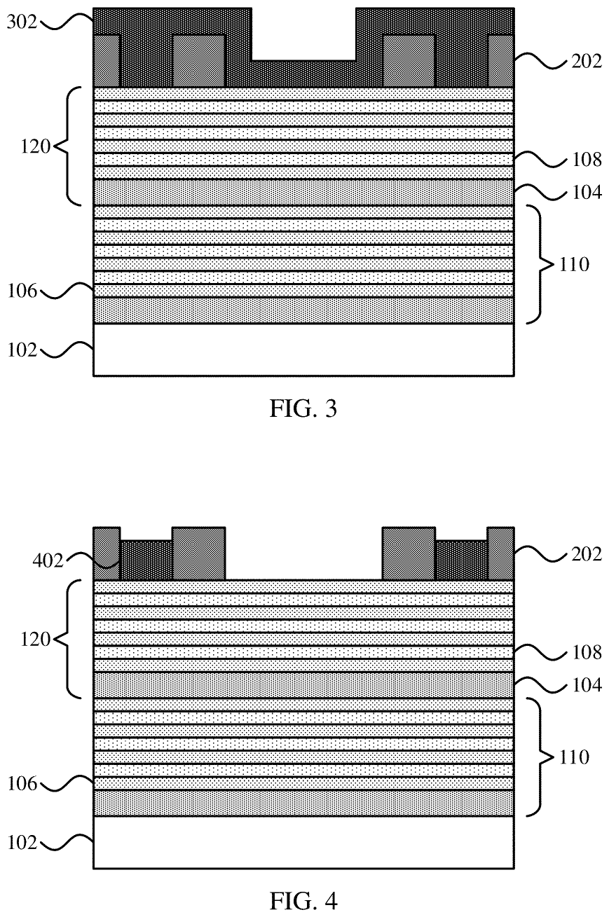

Referring now to FIG. 3, a cross-sectional view of a step in the fabrication of a stacked CMOS device is shown. A layer 302 of a second mask material may be conformally deposited over the first hardmask layers 202. For example, the second mask material may be silicon dioxide, which is selectively etchable with respect to the material of the first mask 202. The second mask material may be deposited to a thickness sufficient to fill the space between the structures of each pair of structures of the first hardmask 202, for example using a conformal deposition process. Thus, for example, the deposition thickness may be greater than half the distance between the structures in each pair of structures of the first mask 202.

As used herein, the term “selective” in reference to a material removal process denotes that the rate of material removal for a first material is greater than the rate of removal for at least another material of the structure to which the material removal process is being applied.

Referring now to FIG. 4, a cross-sectional view of a step in the fabrication of a stacked CMOS device is shown. A second mask 204 is formed on top of the stack of layers. The second mask 402 may be formed etching back the second mask material 302 using a selective anisotropic etch that removes the material from horizontal surfaces, leaving the structures of the second mask 402 filling the space between respective pairs of structures of the first mask 202.

The mask materials may be formed by any appropriate process including, e.g., chemical vapor deposition (CVD) or atomic layer deposition (ALD). CVD is a deposition process in which a deposited species is formed as a result of chemical reaction between gaseous reactants at greater than room temperature (e.g., from about 25° C. about 900° C.). The solid product of the reaction is deposited on the surface on which a film, coating, or layer of the solid product is to be formed. Variations of CVD processes include, but are not limited to, Atmospheric Pressure CVD (APCVD), Low Pressure CVD (LPCVD), Plasma Enhanced CVD (PECVD), and Metal-Organic CVD (MOCVD) and combinations thereof may also be employed. In alternative embodiments that use PVD, a sputtering apparatus may include direct-current diode systems, radio frequency sputtering, magnetron sputtering, or ionized metal plasma sputtering. In alternative embodiments that use ALD, chemical precursors react with the surface of a material one at a time to deposit a thin film on the surface.

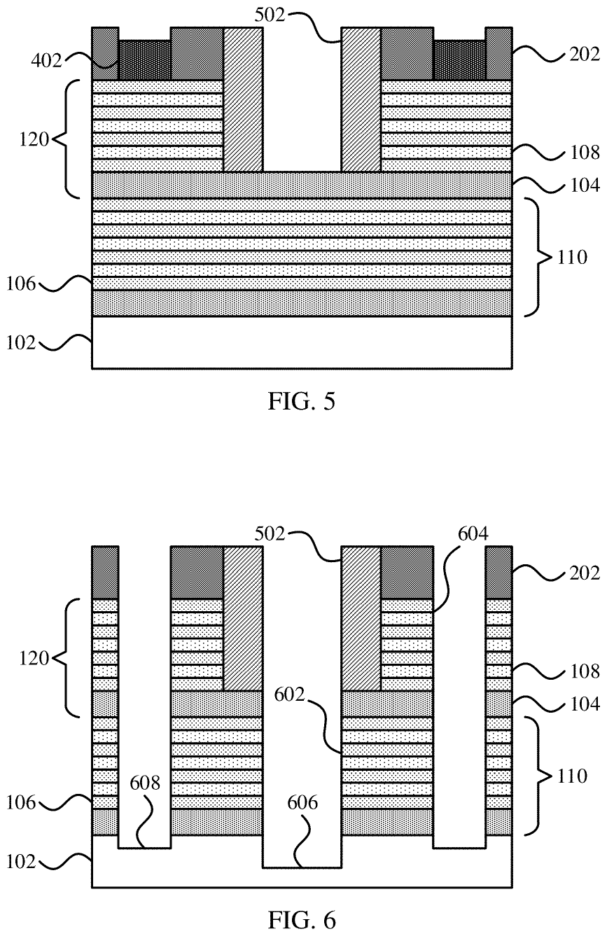

Referring now to FIG. 5, a cross-sectional view of a step in the fabrication of a stacked CMOS device is shown. The channel semiconductor layers 108 and the first sacrificial semiconductor layers 106 of the upper stack 120 are anisotropically etched, for example, by reactive ion etch (RIE), in a region exposed around the first mask 202 and the second mask 402. A single timed etch may be used, or multiple selective etches may be used, to expose the second sacrificial layer 104 of the upper stack 120.

RIE is a form of plasma etching in which during etching the surface to be etched is placed on a radio-frequency powered electrode. Moreover, during RIE the surface to be etched takes on a potential that accelerates the etching species extracted from plasma toward the surface, in which the chemical etching reaction is taking place in the direction normal to the surface. Other examples of anisotropic etching that can be used at this point of the present invention include ion beam etching, plasma etching or laser ablation.

Sacrificial spacers 502 may be formed on the newly exposed sidewalls of the layers of the upper stack 120. The sacrificial spacers 502 may be formed from a spacer material that has etch selectivity with respect to the first mask 202 and the second mask 402, such as silicon oxycarbide. The spacer material may be deposited using a conformal deposition process, such as CVD or ALD, and may be selectively and anisotropically etched from horizontal surfaces to leave the sacrificial spacers 502.

Referring now to FIG. 6, a cross-sectional view of a step in the fabrication of a stacked CMOS device is shown. The second mask 404 is selectively etched away using any appropriate etching process, exposing the top surface of the remaining portions of the upper stack 120. Another anisotropic etching process is used to etch down around the first mask 202 and the sacrificial spacers 502, down through the lower stack 110 and intro the substrate 102. The etch forms relatively wide nanosheet stacks 602 from the lower stack 110 and relatively narrow nanosheet stacks 604 from the upper stack 120. Laterally adjacent stacks are separated by trenches, including relatively wide and deep trench 606 that will be used for a buried power rail and relatively shallow and narrow trenches 608 that may be used for shallow trench isolation (STI).

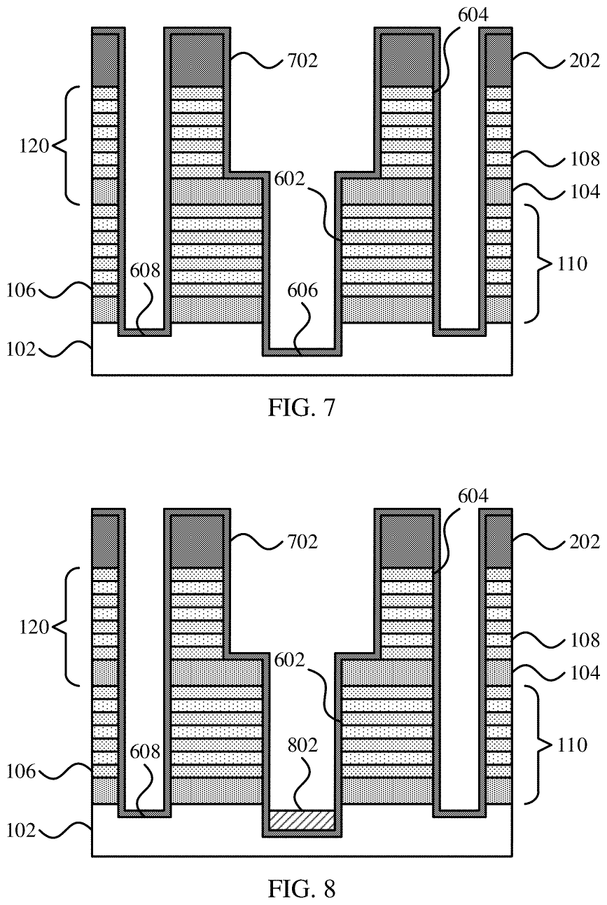

Referring now to FIG. 7, a cross-sectional view of a step in the fabrication of a stacked CMOS device is shown. The third masks 502 are selectively etched away and a first liner layer 702 is conformally deposited. The first liner layer 702 may be formed from any appropriate dielectric material, such as silicon nitride.

Referring now to FIG. 8, a cross-sectional view of a step in the fabrication of a stacked CMOS device is shown. A power rail 802 is formed in the deep trench 606, for example by depositing a conductive material to fill the deep trench 606 and shallow trenches 608 and then recessing the conductive material to remove it from the shallow trenches 608. A planarization process such as chemical mechanical polish (CMP) may be performed after depositing the conductive material and before recessing it. The first liner layer 604 protects the underlying semiconductor layers from the recess of the conductive material.

Any appropriate conductive material can be used to form the power rail 802. Exemplary conductive metals include, e.g., tungsten, nickel, titanium, molybdenum, tantalum, copper, platinum, silver, gold, ruthenium, iridium, rhenium, rhodium, cobalt, and alloys thereof. The power rail 802 may alternatively be formed from a doped semiconductor material such as, e.g., doped polysilicon.

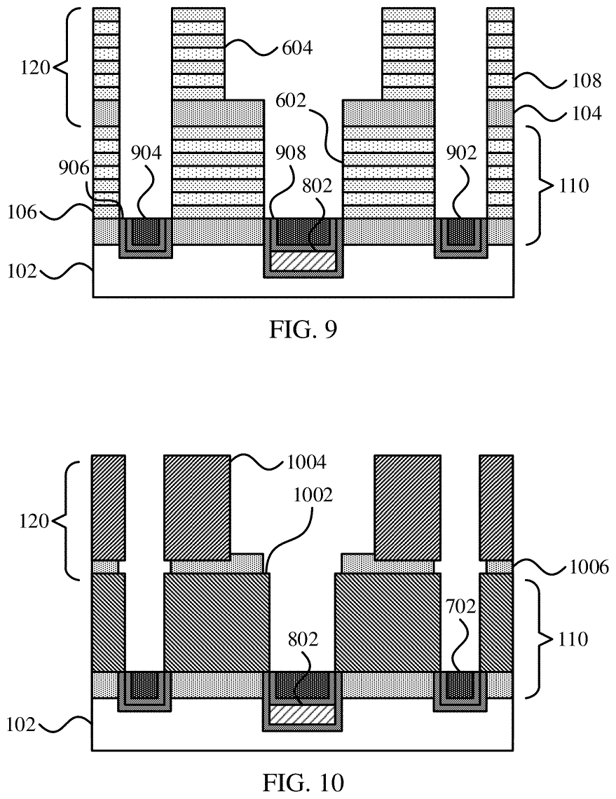

Referring now to FIG. 9, a cross-sectional view of a step in the fabrication of a stacked CMOS device is shown. Additional liner material (e.g., silicon nitride) is conformally deposited, reinforcing the first liner layer 702 in the shallow trenches 608 and burying the power rail 802. Dielectric material, such as silicon dioxide may then be deposited in the trenches. The dielectric material, the additional liner material, and the first liner layer 604 may then be etched back using one or more selective anisotropic etches to form shallow trench isolation structures 902. The shallow trench isolation structures 902 thus include a core 904 of, e.g., silicon dioxide, with a first liner 906 a second liner 908 on the sidewalls and underneath the core 904. For those regions that include a buried power rail 802, the buried power rail 802 is positioned between the first liner 906 and the second liner 908.

The first masks 202, which may be formed from the same material as the first liner 404, may be etched away at this stage, leaving the top surfaces of the top semiconductor stacks 404 exposed. In the case that the first mask layer 202 is different from the liner materials, the mask layer 202 may remain after etching the liner.

Referring now to FIG. 10, a cross-sectional view of a step in the fabrication of a stacked CMOS device is shown. This cross-sectional view is parallel to those shown in the FIGs. above, but is positioned just outside the fins, cutting through a source/drain region, including bottom source/drain structures 1002 and top source/drain structures 1004. A nanosheet transistor fabrication process continues on a different cross-sectional plane, for example where a dummy gate may be formed and the second sacrificial layers 104 are selectively etched away and replaced by isolation dielectric layers 1006. The isolation layers may be formed by etching away the SiGe50 shown in the original .ppt to create a gap between top device stack and bottom device stack, then filling the gap with a dielectric material.

The first sacrificial layers 106 may be recessed relative to the semiconductor channel layers 108, and inner dielectric spacers may be formed. Lower source/drain structures 1002 may be epitaxially grown from sidewalls of the semiconductor channel layers 108 in the lower device region 110, while upper source/drain structures 1004 may be epitaxially grown from the sidewalls of the semiconductor channel layers 108 in the upper device region 120. The lower source/drain structures 1002 and the upper source/drain structures 1004 may be formed with differing dopants, in accordance with a respective device polarity (e.g., n-type or p-type).

There are multiple ways to form the top and bottom source/drains. For example, the first source/drain 1004 can be grown at both top and bottom devices without any mask. The epitaxial source/drain material can then be removed from the top device 120 by recessing. A dielectric cap can then be formed on top of the recessed lower source/1002 drain to cover the bottom device 110, and the top/source drain 1004 can then be epitaxially grown.

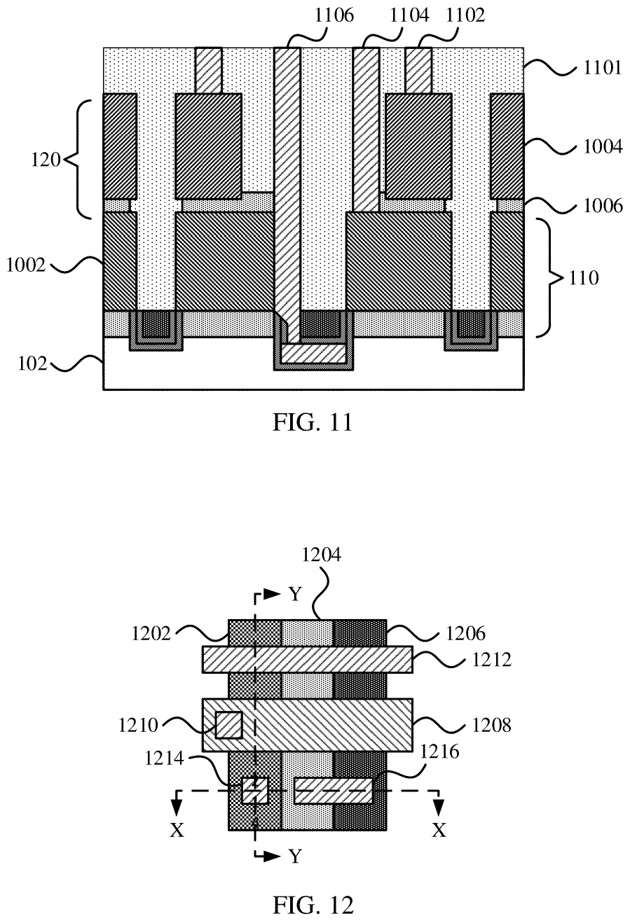

Referring now to FIG. 11, a cross-sectional view of a step in the fabrication of a stacked CMOS device is shown. An interlayer dielectric 1101 is formed, using any appropriate deposition process, such as a flowable CVD of silicon dioxide. Vias are patterned and etched into the interlayer dielectric 1102 using any appropriate process, such as a photolithographic patterning process with an RIE. The vias may then be filled with conductive material to form conductive contacts.

A variety of conductive contact structures are shown. Top contacts 1102 make contact to the top source/drain structures 1004. Two kinds of lower contacts are shown, including a plain contact 1104 and a rail contact 1106. The plain contact 1104 reaches down to the lower source/drain structures 802 and stops there.

The rail contact 1106 reaches down to the buried power rail 1102, and may make contact with the lower source/drain structure 1002 along the way. The via penetrates the STI structure 902 over the buried power rail 802, so that the rail contact 1106 can make electrical contact with the rail 802. Notably, the thick liner of the STI region 802 (including two layers of liner material) helps to prevent short circuits between the rail contact 1106 and the substrate 102. Meanwhile, the buried power rail 802 has only a single layer of liner material around it, maximizing its cross sectional area and hence minimizing the resistance of the buried power rail 802.

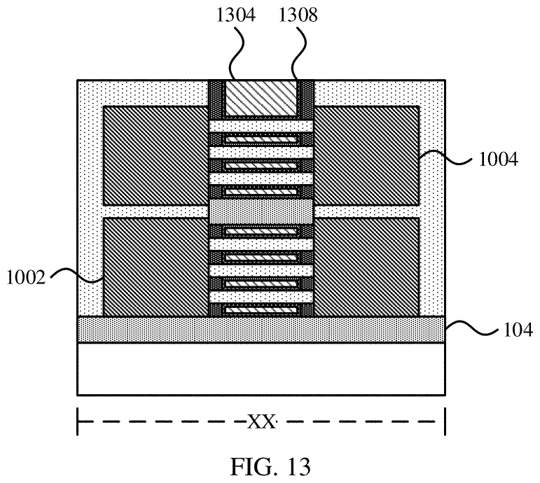

Referring now to FIG. 12, a top-down view of a stacked CMOS device is shown. The top-down view indicates two cross-sectional planes, including the XX plane and the YY plane. FIGS. 1-9 are shown in the XX plane and FIGS. 10-11 are shown parallel to the XX plane.

The top-down view illustrates an exemplary arrangement of contacts. A top device 1202 is shown. A bottom device 1204 is underneath the top device 1202 and extends laterally past the top device 1202. The buried power rail 1206 is located in a layer below the bottom device 1206, to the side of the bottom device 1206. A shared gate 1208 makes contact with the top device 1202 and the bottom device 1204.

A gate contact 1210 makes electrical contact with the gate 1208. A shared source/drain contact 1212 makes electrical contact with both the top device 1202 and the bottom device 1206. A top contact 1214 makes contact with the top device 1202. A bottom contact 1216 makes contact with the bottom device 1204 and may additionally make contact with the buried power rail 1206.

Referring now to FIG. 13, a cross-sectional view of a stacked CMOS device is shown. This view is along the YY cross-sectional plane, showing details regarding the gate stack of the devices. The bottom source/drains 1002 and the top source/drains 104 are shown, along with a gate stack on the channel layers 108 that includes a gate dielectric 1302 and a gate conductor 1304.

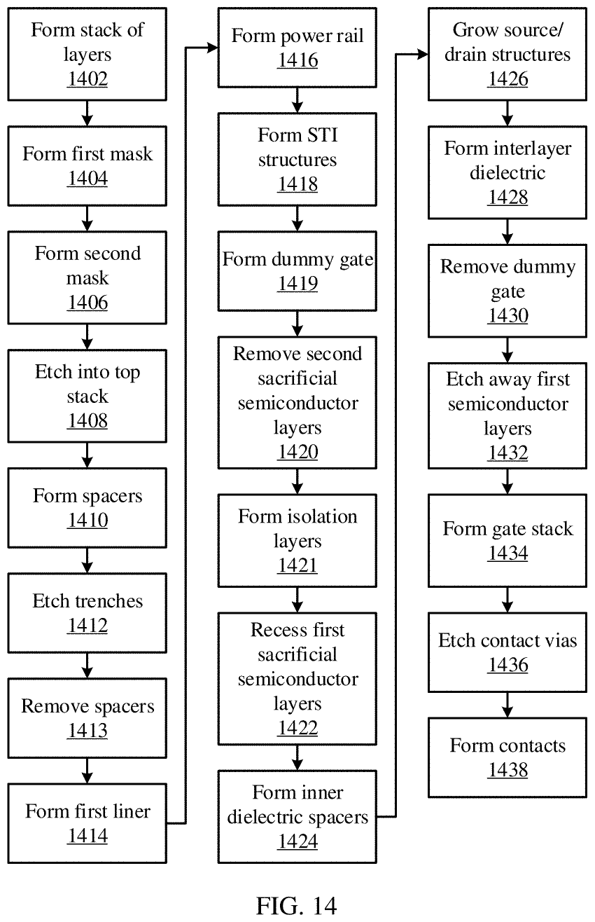

Referring now to FIG. 14, a method of forming stacked CMOS devices is shown. Block 1402 forms a stack of layers on a substrate 102, including channel semiconductor layers 108, first sacrificial semiconductor layers 106, and second sacrificial semiconductor layers 104, divided into at least a lower stack 110 and an upper stack 120. These layers may be epitaxially grown from one another, with each of the layers being formed from crystallographically compatible semiconductor materials, such as silicon and silicon germanium with differing concentrations of germanium.

Block 1404 forms the first mask 202, for example by depositing a layer of silicon nitride and patterning it using photolithography. Block 1406 forms the second mask 402 in gaps between structures of the first mask 202, for example by conformally depositing a second, selectively etchable material, such as silicon dioxide, and then anisotropically etching the material away from other surfaces. Block 1408 uses the first mask 202 and the second mask 402 as a mask pattern to selectively and anisotropically down into the upper stack 120 of semiconductor layers, stopping on an upper second sacrificial semiconductor layer 104.

Block 1410 forms sacrificial spacers 502 from, e.g., silicon oxycarbide, using a conformal deposition process, followed by an anisotropic etch to remove the sacrificial material from horizontal surfaces. Block 1412 etches trenches 606 and 608 into the remaining semiconductor layers, by removing the second mask 402 and using the first mask 202 and the sacrificial spacers 502 as a mask pattern. Block 1413 removes the sacrificial spacers 502 using any appropriate selective etching process.

Block 1414 forms a first liner 702 by conformally depositing a dielectric material, such as silicon nitride, in the trenches 606 and 608. Block 1416 forms power rail 802 in the deeper trench 606, for example by depositing a conductive material in the trenches and then recessing to bring the top surface of the conductive material below a lowest point of the shallow trenches 608. Block 1418 then forms STI structures 902 in the trenches, for example by depositing a second dielectric liner material, depositing a dielectric fill to fill the remaining space of the trenches, and then recessing etching the first dielectric liner 702, the second dielectric liner material, and the dielectric fill.

Block 1419 forms a dummy gate over the stacks. Block 1420 removes the second sacrificial semiconductor layers 104, for example using a selective isotropic etch, such as a wet or dry chemical etch. Block 1421 fills the space left by the removal of the second sacrificial semiconductor layers 104 with a dielectric material, for example using a conformal deposition process, to form isolation layers 1006 that electrically isolate the upper stack 120 from the lower stack 110, and the lower stack 110 from the substrate 102.

Block 1422 recesses the first sacrificial semiconductor layers 106 relative to the channel semiconductor layers using a selective etch that preferentially removes material from the first sacrificial semiconductor layers 106. Block 1424 forms inner dielectric spacers in the recesses, using a conformal deposition process, followed by an anisotropic etch that removes excess material from surfaces that are not protected within the recesses.

Block 1426 grows the lower source/drain structures 1002 from the channel semiconductor layers 108 of the lower stack 110, and further grows the upper source/drain structures 804 from the channel semiconductor layers 108 of the upper stack 110, using respective epitaxial growth processes. Block 1428 forms an interlayer dielectric 1101 around the stacks and the source/drain structures.

At this stage, block 1430 etches away the dummy gate, exposing the stacks of semiconductor layers. Block 1432 removes the remaining portions of the first sacrificial semiconductor layers 106. Block 1434 then forms a gate stack on the channel semiconductor layers 108. The gate stack may include, for example, a gate dielectric layer, an optional work function metal layer, and a gate conductor. The gate dielectric may be formed from any appropriate dielectric material, such as a high-k dielectric, for example to metal oxides such as hafnium oxide, hafnium silicon oxide, hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate. The high-k material may further include dopants such as lanthanum and aluminum.

Block 1436 etches contact vias into the interlayer dielectric 1101, and block 1438 deposits conductive material into the vias to form contacts, for example including upper contacts 1102, lower contacts 1104, and rail contacts 1106.

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys.

Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or features(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” an encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of stacked staircase CMOS with buried power rail (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A method of forming a semiconductor device, comprising:
forming a buried power rail in a substrate, having a first dielectric liner of a first thickness separating the buried power rail from the substrate;
forming an isolation structure over the buried power rail, having a second dielectric liner of a second thickness, greater than the first thickness, separating the isolation structure from the substrate;
forming a first transistor device on the substrate, the first transistor device having a first width;
forming a second transistor device, above the first transistor device, having a second width smaller than the first width; and
forming a conductive contact to the buried power rail.

2. The method of claim 1, wherein forming the conductive contact includes forming a via that exposes a portion of a source/drain structure of the first transistor device.

3. The method of claim 1, wherein forming the conductive contact includes forming a via that cuts partially through the second dielectric liner.

4. The method of claim 1, wherein the first transistor device and the second transistor device together form a first complementary metal oxide semiconductor (CMOS) device, with the first transistor having a first polarity and the second transistor device having a second polarity, opposite to the first polarity.

5. The method of claim 4, further comprising forming a second CMOS device on the substrate, on an opposite side of the buried power rail relative to the first CMOS device.

6. The method of claim 5, further comprising forming a shallow trench isolation structure in the substrate, on a side of the first CMOS device opposite to the buried power rail.

7. The method of claim 6, wherein forming the shallow trench isolation structure includes:
depositing a first dielectric layer, corresponding to the first dielectric liner and a first part of the second dielectric liner, on a trench in the substrate;
depositing a second dielectric layer, corresponding to a second part of the second dielectric liner; and
depositing a dielectric fill in the trench.

8. The method of claim 1, further comprising:
forming a first isolation dielectric layer between the first transistor device and the substrate; and
forming a second isolation dielectric layer between the first transistor device and the second transistor device.

9. The method of claim 1, further comprising forming a mask that includes a region of a second mask material between two regions of a first mask material.

10. The method of claim 9, further comprising:
etching down to a first depth around the mask to form a recess;
depositing a sacrificial spacer on sidewalls of the recess; and
etching down to a second depth in regions around the sacrificial spacer and the first mask material.

11. A method of forming a semiconductor device, comprising:
forming a buried power rail in a substrate, having a first dielectric liner of a first thickness separating the buried power rail from the substrate;
forming an isolation structure over the buried power rail, having a second dielectric liner of a second thickness, greater than the first thickness, separating the isolation structure from the substrate;
forming a first transistor device on the substrate, the first transistor device having a first width;
forming a second transistor device, above the first transistor device, having a second width smaller than the first width;
forming a via that exposes a portion of a source/drain structure of the first transistor device and that cuts partially through the second dielectric liner; and
depositing a conductive material in the via to form a conductive contact to the buried power rail.

12. A semiconductor device, comprising:
a buried power rail in a substrate, having a first dielectric liner of a first thickness separating the buried power rail from the substrate;
an isolation structure over the buried power rail, having a second dielectric liner of a second thickness, greater than the first thickness, separating the isolation structure from the substrate
a first transistor device on the substrate, the first transistor device having a first width;
a second transistor device, above the first transistor device, having a second width smaller than the first width; and
a conductive contact to the buried power rail.

13. The semiconductor device of claim 12, wherein the conductive contact contacts a source/drain structure of the first transistor device.

14. The semiconductor device of claim 12, wherein the first transistor device and the second transistor device together form a first complementary metal oxide semiconductor (CMOS) device, with the first transistor having a first polarity and the second transistor device having a second polarity, opposite to the first polarity.

15. The semiconductor device of claim 14, further comprising a second CMOS device on the substrate, on an opposite side of the buried power rail relative to the first CMOS device.

16. The semiconductor device of claim 15, further comprising a shallow trench isolation structure in the substrate, on a side of the first CMOS device opposite to the buried power rail.

17. The semiconductor device of claim 16, wherein the shallow trench isolation structure includes a first dielectric layer, corresponding to the first dielectric liner and to a first part of the second dielectric liner, a second dielectric layer, corresponding to a second part of the second dielectric liner, and a dielectric fill.

18. The semiconductor device of claim 16, wherein the buried power rail has a depth in the substrate that is greater than a depth of the shallow trench isolation structure.

19. The semiconductor device of claim 12, further comprising:
a first isolation dielectric layer between the first transistor device and the substrate; and
a second isolation dielectric layer between the first transistor device and the second transistor device.

20. The semiconductor device of claim 12, wherein the second transistor device is positioned over a side of the first transistor device opposite to the buried power rail.
